(19) United States
(12) Patent Application Publication
(10) Pub. No.: US 2005/0059260 A1
(43) Pub. Date: Mar. 17, 2005

(54) CMOS transistors and methods of forming same

(76) Inventors: Haowen Bu, Plano, TX (US); Brian Hornung, Richardson, TX (US); P.R. Chidambaram, Richardson, TX (US); Amitabh Jain, Allen, TX (US); Rajesh Khamankar, Coppell, TX (US); Nandu Mahalingam, Richardson, TX (US); Srinivansan Chakravarthi, Murphy, TX (US)

Correspondence Address: TEXAS INSTRUMENTS INCORPORATED, P O BOX 655474, M/S 3999, DALLAS, TX, 75265, US

(21) Appl. No.: 10/810,905

(22) Filed: Mar. 26, 2004

Related U.S. Application Data
(63) Continuation-in-part of application No. 10/662,850, filed on Sep. 15, 2003.

(51) Int. Cl. H01L 21/336; H01L 21/8238; H01L 29/76

(52) U.S. Cl. 438/775; 438/199; 257/288

(57) ABSTRACT

The present invention teaches the formation of CMOS transistors using interfacial nitrogen at the interface between the lightly doped extension regions and an overlying insulating layer in combination with a capping layer of silicon nitride, both prior to the final source/drain anneal. Doses and energies may be increased for the P-channel lightly-doped drain, source and drain regions. The resulting transistors exhibit desirably high drive current and low off-state leakage current and overlap capacitance.

### CROSS-REFERENCE TO RELATED PATENT APPLICATIONS

This application is a continuation-in-part of U.S. patent application Ser. No. 10/662,850, filed Sep. 15, 2003, titled: Integration of Pre-S/D Anneal Selective Nitride/Oxide Composite Cap for Improving Transistor Performance, by Bu, H. et al, the entirety of which is incorporated herein by reference.

### FIELD OF THE INVENTION

The present invention relates generally to complementary metal oxide semiconductor (MOS) transistors and more particularly to methods for forming CMOS transistors having improved operating characteristics.

### BACKGROUND OF THE INVENTION

Shown in FIG. 1 is a cross-sectional diagram of a typical metal oxide semiconductor (MOS) transistor 5. The MOS transistor 5 is fabricated in a semiconductor substrate 10. The MOS transistor comprises a gate dielectric layer 20 that is formed on the surface of the substrate 10. Typically this gate dielectric layer is formed using silicon oxide or nitrided silicon oxide although many other materials such as silicates have been used. The MOS transistor gate structure 30 is formed on the gate dielectric layer 20 and is typically formed using polycrystalline silicon. In addition to polycrystalline silicon, other materials such as metals have been used to form the transistor gate.

The combined dielectric layer/gate structure is typically referred to as the gate stack. Following the formation of the transistor gate stack the source-drain extension regions 40 are formed using ion implantation. In forming these extension regions 40 dopants are implanted into the substrate using the gate stack as a mask. Using this process, the extension regions 40 are aligned to the gate stack in what is known as a self-aligned dopant implantation process. Following the formation of the extension regions 40, sidewall structures 50 are formed adjacent to the gate stack. These sidewall structures 50 are typically formed by depositing one or more conformal films on the surface of the substrate followed by an anisotropic etch process. This anisotropic etch will remove the conformal film from all horizontal regions of the surface, leaving the vertical spacers or sidewall structures 50 adjacent to the gate stack structure as shown in FIG. 1.

Following the formation of the sidewall structures the source and drain regions 60 are formed using ion implantation. The structure is then annealed at a high temperature to activate the implanted dopant species in both the extension regions 40 and the source and drain regions 60. During this high temperature anneal the dopants will diffuse into the semiconductor substrate. This dopant diffusion will result in a final junction depth of xⱼ for the extension regions 40. It will be understood by the reader that while FIG. 1 shows a single MOS transistor device 5, typically thousands or millions of such devices are incorporated onto substrate 10. Further, the doping of substrate 10 alternates from P-type to N-type across the substrate, creating complimentary P— and N-type transistors (CMOS) with appropriately doped source, drain and extension regions.

As CMOS transistor dimensions are reduced there is a need to reduce the junction depth xⱼ, and in particular, the lateral junction distance yⱼ of the extension regions 40 while keeping source-drain extension sheet resistance low. Typically, shallow junction depth is accomplished by reducing the implantation dose and energy of the dopant species used to form the extension regions 40. This often leads to an increase in the source-drain resistance of the MOS transistor, and results in degradation of the MOS transistor performance. There is therefore a need to simultaneously reduce the extension junction depth xⱼ and length yⱼ, and lower the source-drain extension sheet resistance.

U.S. Pat. No. 6,677,201 to Bu et al., incorporated herein by reference in its entirety, shows a method for forming CMOS transistors wherein an interfacial nitrogen is used at the interface between a sidewall cap oxide and a silicon substrate for a shallow junction to improve operation of P-channel devices, with no improvement/degradation to the N-channel devices.

No single process has yet been provided which, to the inventor's knowledge, optimizes the performance of the P— and N-channel devices in a CMOS chip without diminishing the performance of the other.

### SUMMARY OF THE INVENTION

The instant invention provides methods and systems for forming CMOS transistors that incorporate process steps for simultaneously improving the operation of both the P— and N-channel MOS devices. Further provided are the resulting improved device structures. More particularly there are provided herein solutions to obtaining more abrupt lateral profiles in ultra-shallow extension regions for improved CMOS transistor performance. As a result, the implant dose and/or energy at PLDD can be reasonably high to maintain a relatively low source-drain extension sheet resistance R_{sd}, while keeping gate-to-drain overlap capacitance and off-state leakage current in control.

In accordance with one embodiment of the invention there is provided a method for fabricating a CMOS transistor structure, comprising the steps of: providing a semiconductor substrate having a P-type dopant region to support an N-channel transistor and an N-type dopant region to support a P-channel transistor, each of the N-type dopant and P-type dopant regions having an overlying gate stack including a conductive gate; forming lightly-doped extension regions in the semiconductor substrate adjacent each gate stack; forming a layer of insulating material over the lightly-doped extension regions; forming an interfacial layer of nitrogen at the interface of the insulating layer and the lightly-doped extension regions; forming source and drain regions in the semiconductor substrate adjacent to each of the gate stacks; forming a capping layer of contiguous silicon nitride over the semiconductor substrate and each of the gate stacks; annealing, with the capping layer in place, the extension and source and drain regions; and removing the capping layer after the annealing.

In accordance with another embodiment of the invention there is provided a semiconductor structure formed in the process of fabricating a CMOS transistors prior to an activating anneal, comprising: a semiconductor substrate having an P-type dopant region to support an NMOS transistor and a N-type dopant region to support a PMOS transistor, each of the N-type dopant and P-type dopant regions having an overlying gate stack including a conductive gate; a layer of insulating material over the semiconductor substrate and gate stack; lightly-doped extension regions in the semiconductor substrate adjacent each gate stack; an interfacial layer of nitrogen formed at the interface of the lighted-doped extension regions and the layer of insulating material; source and drain regions in the semiconductor substrate adjacent to each of the gate stacks; and a capping layer of contiguous silicon nitride over the semiconductor substrate and each of the gate stacks.

### BRIEF DESCRIPTION OF THE DRAWINGS FIGURES

These and other objects, features and advantages of the invention will be understood through a consideration of the detailed description of the invention when read in conjunction with the drawing Figures, in which:

FIG. 1 is a cross-sectional view of an MOS transistor constructed in accordance with the prior art; and

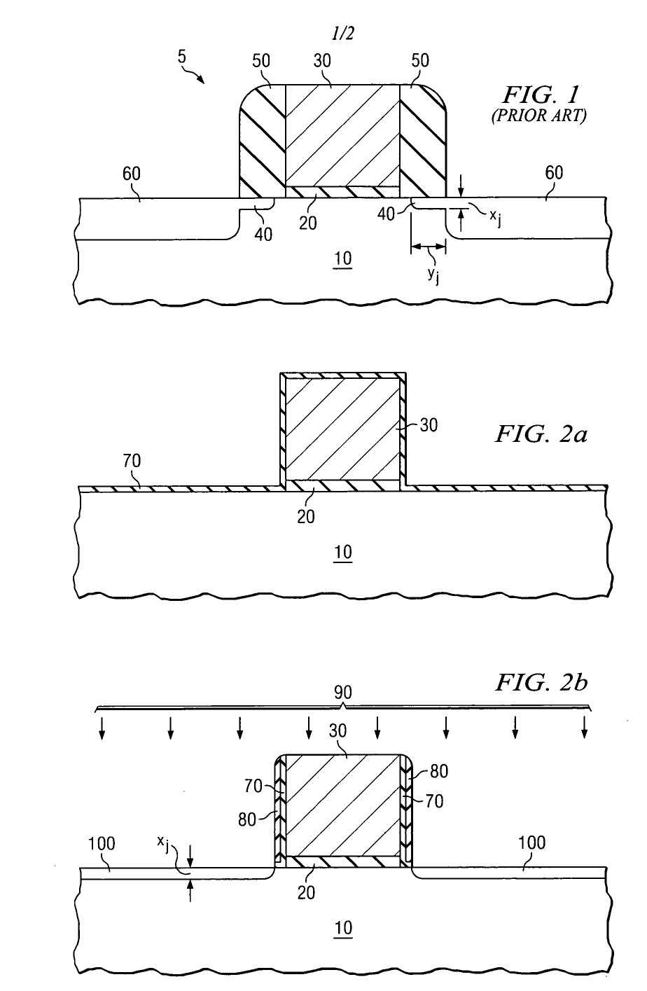

FIGS. 2A-2D are cross-sectional views illustrating consecutive steps in the formation of a CMOS device in accordance with the present invention.

### DETAILED DESCRIPTION OF THE INVENTION

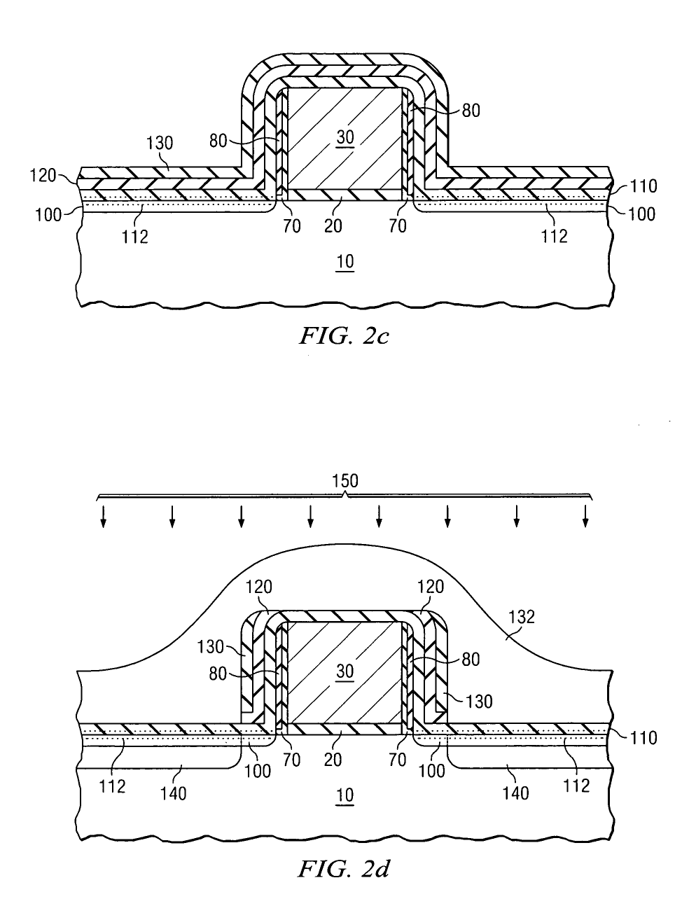

With reference to FIG. 2(a) the MOS transistors of the instant invention are fabricated on a semiconductor substrate 10. In one embodiment of the invention the substrate 10 is a silicon substrate with or without an epitaxial layer. The MOS transistors of the instant invention can also be formed on a silicon-on-insulator substrate that contains a buried insulator layer. Each MOS transistor is fabricated within an n-type or a p-type dopant region, or well, that is formed in the substrate 10. For purposes of illustrating the present invention, substrate 10 comprises an n-type well for the formation of a PMOS, or P-channel MOS transistor. It will be understood that an NMOS, or N-channel MOS transistor is formed in the identical manner within an adjacent p-type well (not shown).

In forming the MOS transistors of the instant invention, a gate dielectric region 20 is formed on the substrate 10. The gate dielectric region 20 can be formed using silicon oxide, silicon oxynitride, alternating layers of silicon oxide and silicon nitride, or any suitable dielectric material. Following the formation of the gate dielectric layer 20, a blanket layer of polycrystalline silicon, a metal, or any suitable gate material is formed on the gate dielectric layer 20. Photolithography and dry etching techniques are then used in a conventional manner to pattern and etch the blanket layer to form the transistor gate 30. The dielectric layer 20 and gate 30 are referred to herein as the gate stack. In the described embodiment, polycrystalline silicon is used to form layer 30 in the gate stack, and a thermal oxidation process or a chemical vapor deposition (CVD) process is performed to grow a layer of silicon oxide 70 shown in FIG. 2(a). In an embodiment of the instant invention the silicon oxide layer 70 is between 10 Å and 70 Å in thickness.

Following the formation of the silicon oxide layer 70, optional offset spacer structures 80 are formed as shown in FIG. 2(b). In the described embodiment of the instant invention, the offset spacer structures 80 are formed by first depositing a conformal layer of silicon nitride over the silicon oxide layer 70. An anisotropic dry etch process is then used to remove the horizontal regions of the silicon nitride layer resulting in the sidewall spacer structures 80. Source-drain extension (extension) regions 100 are then formed in the substrate 10 by the ion implantation of various dopant species 90. The as-formed implanted extension regions 100 (i.e. prior to any high temperature thermal annealing) are thus self-aligned to the edge of the sidewall spacer structures 80.

For PMOS transistors the implantation process can comprise a single or multiple implantation steps using p-type dopants such as boron and BF₂. In addition, other implants such as those used to form the pocket regions can also be performed at this time. For NMOS transistors the implantation process can comprise a single or multiple implantation steps using n-type dopants such as arsenic and phosphorous. Other implants such as those used to form the pocket regions can also be performed at this time.

One key feature of the invention is the abrupt, shallow junction depths achieved in the extension regions 100. To achieve these junction profiles, the implanted dopant is placed close to the surface of the substrate 10, allowing for dopant diffusion during a subsequent high temperature anneal described below. The high temperature anneal process is typically a rapid thermal annealing (RTA) process. The junction depth of the extension during the high anneal is reduced using the methodology of the instant invention, thereby improving the operating characteristics of the transistor.

Following the formation of the extension regions 100 and prior to any high temperature annealing, a number of layers are formed on the structure of FIG. 2(b). In the described embodiment of the invention, three layers are formed as shown in FIG. 2(c). The first layer 110 is a deposited silicon oxide layer. Prior to the formation of oxide layer 110, in accordance with the present invention, an interfacial layer 112 of nitrogen having an atomic nitrogen concentration in the range of 2 to 15 atomic percent is incorporated into the upper surfaces of extension regions 100, subsequently forming an interface between oxide layer 110 and the extension region 100.

In the described embodiment of the instant invention, interfacial layer 112 is formed by first annealing the structure of FIG. 2b in ammonia (NH₃) prior to the deposition of layer 110. The ammonia anneal and subsequent deposition of oxide layer 110 can be performed with a single recipe in the same process tool. For example, the ammonia anneal is performed at a temperature of 600-750 degrees centigrade for less than one minute, at a pressure in the range of 1-300 torr, in an single-wafer rapid thermal chemical deposition (RTCVD) chamber. The oxide deposition can follow the ammonia anneal without breaking vacuum, using silane (SiH₄) and nitrous oxide (N₂O) as the reactive gases.

The process of forming the oxide layer with interfacial nitrogen can also be accomplished in a batch furnace. In this embodiment, the ammonia anneal is similarly first performed prior to the oxide deposition. Using a batch furnace process, tetraethylorthosilicate (TEOS) is widely used for the deposition of the oxide layer, typically at deposition temperature of 550-700 degrees centigrade.

Regardless of the formation process used, it is advantageous to cap the interfacial layer 112 with the oxide layer 110 without breaking vacuum. Exposing wafers to ambient after the formation of layer 112 tends to cause nitrogen dose loss and the amount of the dose loss may vary depending on the how long the wafers are exposed to ambient after nitrogen is incorporated.

Other methods will now be apparent for forming the interfacial nitrogen layer, for example by incorporating nitrogen using other techniques such as plasma nitridation or low energy nitrogen implant.

Following the formation of the oxide layer 110, a silicon nitride layer 120 is formed. In an embodiment of the instant invention the silicon nitride layer 120 is formed using a CVD bis t-ButylaminoSilane (BTBAS) process. In this process BTBAS (SiH₂ (t-BuNH)₂) along with NH₃ and other gases such as nitrogen are used to deposit the silicon nitride layer 120 at temperatures in the range of 475-650 degrees C. Following the formation of the silicon nitride layer 120, a silicon oxide layer 130 is formed. In the described embodiment of the invention the silicon oxide layer 130 is formed using a single wafer chemical vapor deposition process at temperatures between 550 and 750 degrees C. The process can be accomplished in a batch furnace using tetraethylorthosilicate (TEOS) for oxide deposition, at deposition temperature in the range of 550-700 degrees C.

As shown in FIG. 2(d) regions of the layers 120 and 130 are removed to leave sidewall spacers over the gate stack. In the present embodiment of the invention anisotropic silicon oxide and silicon nitride etch processes are used to remove the unwanted regions of layers 120 and 130. Following the sidewall formation process the extension regions 100 are still covered by the silicon oxide layer 110, even though some of layer 110 might have been removed during the anisotropic silicon nitride etch process. After the sidewall formation process an optional thermal anneal can be performed.

The source and drain regions 140 are then formed by implanting dopant species 150 into the substrate. For PMOS transistors the implantation process can comprise a single or multiple implantation steps using p-type dopants such as boron and/or BF₂. For NMOS transistors the implantation process can comprise a single or multiple implantation steps using n-type dopants such as arsenic and/or phosphorous.

With reference still to FIG. 2(d), in accordance with one aspect of the present invention, a relatively thick coating in the range of 200-1,000 Å of silicon nitride 132 is deposited conformally over the upper surfaces of the device. Layer 132 is preferably deposited using a plasma enhanced chemical vapor deposition (PECVD) process such as using SiH₄ and NH₃ as reactive gases at a temperature in the range of 300-500 degrees C. to produce a nitride film with tensile stress and high hydrogen concentration.

Following the formation of nitride layer 132, a thermal anneal is performed to activate the implanted dopant. In a particular embodiment the high temperature anneal comprises a rapid thermal anneal in the range of 1000 to 1100 degrees C., for example in the range of several seconds.

Subsequent to the thermal anneal, the nitride cap layer is removed by wet etch, in a suitable acidic solution such as hot phosphorous acid. Conventional back-end processing is performed to form metal layers and connections to gate 30, thereby completing the formation of a CMOS semiconductor chip.

In accordance with the present invention, the interfacial layer of N formed in the interface between oxide layer 110 and the extension region 100 (see FIG. 2(c) above) in combination with the pre-anneal deposition of nitride cap 132, and increased dose and/or energy at PLDD ultimately maintain the sheet resistance of substrate 10 while keeping the overlap capacitance in control. As a result, the drive current and off-state leakage current of the PMOS transistors are not degraded due to the pre-anneal deposition of the silicon nitride cap. Comparing to the selective nitride cap approach, this approach is simpler since it does not involve the process steps to selectively remove the nitride cap on PMOS.

The present inventors theorize that the blanked deposition of nitride layer 132 help to exert tensile-strained stress in the channel region. In addition, the diffusion of the lightly-doped source-drain regions in the N-channel devices is modified such that a retrograde boron profile is created due to the presence of nitride at anneal. However, the presence of nitride on the PMOS area simultaneously causes the boron dopant loss at PLDD and PSD, leading to degradation of PMOS transistors. However, in accordance with the present invention, the interfacial nitrogen 112 incorporated into layer 100 diminishes the lateral diffusion of the corresponding regions in the P-channel devices, protecting or enhancing the operating characteristics of those devices when a blanket silicon nitride cap layer is deposited and PLDD implant dose and/or energy are increased accordingly. In comparison to the prior art, it is not required in the practice of the present invention that nitride layer 132 be removed over the P-channel devices.

In alternate embodiments of the invention, if the drain extension regions, or lightly-doped drain (LDD) regions 100 in the P-channel devices, are implanted through a full or partial poly oxide layer, the interfacial nitride may be incorporated after the poly oxide is formed and before the P-type LDD is formed, using the NH₃ and/or N plasma or N low energy implant techniques described above. The interfacial nitrogen may also be incorporated through sidewall cap oxide layer 130 but at the risk of diminishing the etch selectivity with which the sidewall cap is formed.

The present inventors have further determined that with the formation of oxide layer 110, the dopant concentration and/or energy of the P-type LDD in the P-channel devices may be increased, reducing the parasitic sheet resistance, and therefore improving transistor drive current while maintaining leakage current low.

The present inventors have further determined that the instant invention is not limited to the pre-anneal silicon nitride cap application. It can be used to alleviate the similar problems caused by silicon nitride deposited prior to dopant activation anneal in any front end step. For example, one of the embodiments of the instant invention is associated with the sidewall spacer nitride layer 120 in FIG. 2(c) if the nitride film is deposited with an non-carbon containing precursor such as dichlorosilane (DCS) or silane, rather than BTBAS with ammonia.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

1. A method for fabricating a CMOS transistor structure, comprising the steps of:
providing a semiconductor substrate having a P-type dopant region to support an N-channel transistor and an N-type dopant region to support a P-channel transistor, each of the N-type dopant and P-type dopant regions having an overlying gate stack including a conductive gate;
forming lightly-doped extension regions in the semiconductor substrate adjacent each gate stack;
forming a layer of insulating material over the lightly-doped extension regions;
forming an interfacial layer of nitrogen at the interface of the insulating layer and the lightly-doped extension regions;
forming source and drain regions in the semiconductor substrate adjacent to each of the gate stacks;
forming a capping layer of contiguous silicon nitride over the semiconductor substrate and each of the gate stacks;
annealing, with the capping layer in place, the extension and source and drain regions; and
removing the capping layer after the annealing.

2. The method of claim 1 wherein the extension regions for the PMOS transistors have a dopant concentration in the range of about 1-2 e20 atoms/cm3.

3. The method of claim 1 wherein the source and drain regions for the PMOS transistors have a dopant concentration in the range of about 1-2 e20 atoms/cm3.

4. The method of claim 1 wherein said interfacial nitride layer has an atomic nitrogen concentration in the range of 2-15 atomic percent.

5. The method of claim 1 wherein the insulting layer is selected from the group comprising silicon nitride and silicon oxide.

6. The method of claim 1 wherein the step of forming an interfacial layer of nitrogen is performed using one of the methods selected from the group comprising an NH₃ thermal annealing, an NH₃ or N₂ plasma treatment, or an N implantation.

7. The method of claim 1 wherein the capping layer has a thickness in the range of 200-1000 angstroms.

8. The method of claim 1 wherein the annealing step is performed in the range of 1000-1100 degrees centigrade for a time in the range of less than about 10 seconds.

9. The method of claim 1 wherein said gate stack further includes a nitride sidewall deposited with a BTBAS precursor.

10. A method for fabricating a CMOS transistor structure, comprising the steps of:
providing a semiconductor substrate having an N-type dopant region to support an PMOS transistor and a P-type dopant region to support a NMOS transistor, each of the N-type dopant and P-type dopant regions having an overlying gate stack including a conductive gate;
forming lightly-doped extension regions in the semiconductor substrate adjacent each gate stack, the lightly-doped extension regions in the N-type dopant region comprising a P-type dopant having a dopant concentration in the range of about 1-2 e20 atoms/cm3;
forming a layer of silicon oxide over the lightly-doped extension regions;
forming an interfacial layer of nitrogen between the lightly-doped extension regions and the silicon oxide layer, the interfacial layer of nitrogen having an atomic nitrogen concentration in the range of 2-15 atomic percent;
forming source and drain regions in the semiconductor substrate adjacent to each of the gate stacks, the source and drain regions in the in the N-type dopant region comprising a P-type dopant having a concentration in the range of about 1-2 e20 atoms/cm3;
forming a capping layer of contiguous silicon nitride having a thickness in the range of about 200-1000 angstroms over the semiconductor substrate and each of the gate stacks;
annealing, with the capping layer in place, the extension and source and drain regions at a temperature in the range of 1000-1100 degrees centigrade for a period in the range of less than about 10 seconds; and
removing the nitride cap after the annealing.

11. A semiconductor structure formed in the process of fabricating a CMOS transistor structure prior to an activating anneal, comprising:
a semiconductor substrate having an P-type dopant region to support an NMOS transistor and a N-type dopant region to support a PMOS transistor, each of the N-type dopant and P-type dopant regions having an overlying gate stack including a conductive gate;
a layer of insulating material over the semiconductor substrate and gate stack;
lightly-doped extension regions in the semiconductor substrate adjacent each gate stack;
an interfacial layer of nitrogen formed at the interface of the lighted-doped extension regions and the layer of insulating material;
source and drain regions in the semiconductor substrate adjacent to each of the gate stacks; and
a capping layer of contiguous silicon nitride over the semiconductor substrate and each of the gate stacks.

12. The structure of claim 11 wherein the layer of insulating material is silicon oxide.

13. The structure of claim 11 wherein the extension regions for the PMOS transistors have a dopant concentration in the range of about 1-2 e20 atoms/cm3.

14. The structure of claim 11 wherein the source and drain regions for the PMOS transistors have a dopant concentration in the range of about 1-2 e20 atoms/cm3.

15. The structure of claim 11 wherein the interfacial nitride layer has an atomic nitrogen concentration in the range of 2-15 atomic percent.

16. The structure of claim 11 wherein the capping layer has a thickness in the range of 200-1000 angstroms.

17. The structure of claim 11 wherein the gate stack further includes a nitride sidewall deposited with BTBAS precursor.

18. A structure formed in the fabrication of a CMOS transistor semiconductor chip prior to an activating thermal anneal, comprising:
a semiconductor substrate having a P-type dopant region to support an NMOS transistor and an N-type dopant region to support a PMOS transistor, each of the N-type dopant and P-type dopant regions having an overlying gate stack including a conductive gate supporting an oxide sidewall;
lightly-doped extension regions in the semiconductor substrate adjacent each gate stack, the lightly-doped extension regions in the N-type dopant region comprising a P-type dopant having a dopant concentration in the range of about 1-2 e20 atoms/cm3;
a layer of silicon oxide over the lightly doped extension regions;
an interfacial layer of nitrogen at the interface between the layer of silicon oxide and the lightly-doped extension regions, the interfacial layer of nitrogen having an atomic nitrogen concentration in the range of 2-15 atomic percent;
source and drain regions in the semiconductor substrate adjacent to each of the gate stacks, the source and drain regions in the N-type dopant region comprising a P-type dopant having a concentration in the range of about 1-2 e20 atoms/cm3; and
a capping layer of contiguous silicon nitride having a thickness in the range of about 200-1000 angstroms over the semiconductor substrate and each of the gate stacks.
